(19) United States
(12) Patent Application Publication
(10) Pub. No.: US 2008/0032498 A1
(43) Pub. Date: Feb. 7, 2008

(54) METHOD FOR FABRICATING METAL LINE OF SEMICONDUCTOR DEVICE

(76) Inventor: SANG CHUL KIM, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/831,726

(22) Filed: Jul. 31, 2007

(30) Foreign Application Priority Data
Aug. 3, 2006 (KR) 10-2006-0073418

(51) Int. Cl. H01L 21/4763

(52) U.S. Cl. 438/633; 257/E21.577; 257/E21.583; 257/E21.585

(57) ABSTRACT

Provided is a method for fabricating a metal line of a semiconductor device. In a method according to one embodiment, an interlayer insulating layer is formed on a semiconductor substrate. After that, a first trench and a second trench having a wider width than that of the first trench are formed in the interlayer insulating layer. A seed layer is formed on the semiconductor substrate including the first and second trenches, and a first copper layer is formed on the seed layer. Subsequently, the first copper layer is polished until the interlayer insulating layer is exposed, and a second copper layer is formed on the first copper layer. Then, the second copper layer is planarized to form a copper line.

### CROSS-REFERENCE TO RELATED APPLICATION

The present application claims the benefit under 35 U.S.C. §119 of Korean Patent Application No. 10-2006-0073418, filed Aug. 3, 2006, which is hereby incorporated by reference in its entirety.

### BACKGROUND

As semiconductor devices are formed to operate in high speed and become highly integrated, metal lines formed in the semiconductor devices are micronized and multilayered. When the width of a metal line becomes narrow, the resistance and capacitance of the metal line increases, which causes signal delay. To reduce this signal delay, the metal line is being formed of copper, which is a low resistance metal.

A metal line is usually formed by patterning a metal layer through an etching process using a photoresist. However, since copper is not easily etched and interlayer adhesiveness is poor, metal lines formed of copper utilize a damascene process.

According to the damascene process, a trench is formed in a substrate, and a portion of the substrate including the trench is plated with a copper layer. After that, the substrate is planarized using chemical mechanical polishing (CMP) to form a copper line.

Examples of plating processes include electro-plating (EP) and electroless plating (ELP). In the electro-plating, the speeds of forming a copper layer are different in a region where the width of a copper line is narrow compared to a region where the width of a copper line is wide, which causes a height difference in the layer formation. When the height difference occurs, a degree of polishing varies when the CMP is performed. Also, the copper layer is formed over the entire surface of a wafer stained with an electrolyte solution.

In the electroless plating, the speed of forming a copper layer is slow compared to that of the electro-plating when forming the copper layer, which reduces productivity.

### BRIEF SUMMARY

Embodiments of the present invention provide a method for fabricating a metal line of a semiconductor device that can compensate for limitations of electroplating and electroless plating. In an embodiment, productivity can be improved, and an influence of a height difference generated by the difference in line widths can be minimized to fabricate a planarized substrate surface.

In one embodiment, a method for fabricating a metal line of a semiconductor device comprises: forming an interlayer insulating layer on a semiconductor substrate; forming a first trench and a second trench having a wider width than that of the first trench in the interlayer insulating layer; forming a seed layer on the semiconductor substrate including the first and second trenches; forming a first copper layer on the seed layer; polishing the first copper layer until the interlayer insulating layer is exposed; forming a second copper layer on the first copper layer; and planarizing the second copper layer to form a copper line.

In another embodiment, a method for fabricating a metal line of a semiconductor device comprises: forming an interlayer insulating layer on a semiconductor substrate; forming a first trench and a second trench having a wider width than that of the first trench in the interlayer insulating layer; forming a seed layer on the semiconductor substrate including the first and second trenches; forming a copper layer on the seed layer; forming a sacrificial layer on a height difference region of the copper layer generated by a width difference between the first and second trenches to planarize the copper layer; and polishing the copper layer and the sacrificial layer until the interlayer insulating layer is exposed.

The details of one or more embodiments are set forth in the accompanying drawings and the description below. Other features will be apparent from the description and drawings, and from the claims.

### BRIEF DESCRIPTION OF THE DRAWINGS

FIGS. 1-6 illustrate a method for fabricating a metal line of a semiconductor device according to an embodiment of the present invention.

FIG. 1 is a cross-sectional view of a device shape after a via has been formed according to an embodiment.

FIG. 2 is a cross-sectional view of a device shape after a trench has been formed according to an embodiment.

FIG. 3 is a cross-sectional view of a device shape after a first copper layer has been formed according to an embodiment.

FIG. 4 is a cross-sectional view of a device shape after a line has been short-circuited according to an embodiment.

FIG. 5 is a cross-sectional view of a device shape after a second copper layer has been formed according to an embodiment.

FIG. 6 is a cross-sectional view of a device shape after a second copper layer has been planarized according to an embodiment.

FIGS. 7-12 illustrate a method for fabricating a metal line of a semiconductor device according to another embodiment of the present invention.

FIG. 7 is a cross-sectional view of a device shape after a via has been formed according to an embodiment.

FIG. 8 is a cross-sectional view of a device shape after a trench has been formed according to an embodiment.

FIG. 9 is a cross-sectional view of a device shape after a seed layer has been formed in a method for fabricating a metal line of a semiconductor device according to another embodiment.

FIG. 10 is a cross-sectional view of a device shape after a copper layer has been formed according to an embodiment.

FIG. 11 is a cross-sectional view of a device shape after a sacrificial layer has been formed according to an embodiment.

FIG. 12 is a cross-sectional view of a device shape after a copper layer and a sacrificial layer have been removed according to an embodiment.

### DETAILED DESCRIPTION

A method for fabricating a metal line of a semiconductor device according to embodiments of the present invention will be descried below with reference to the accompanying drawings.

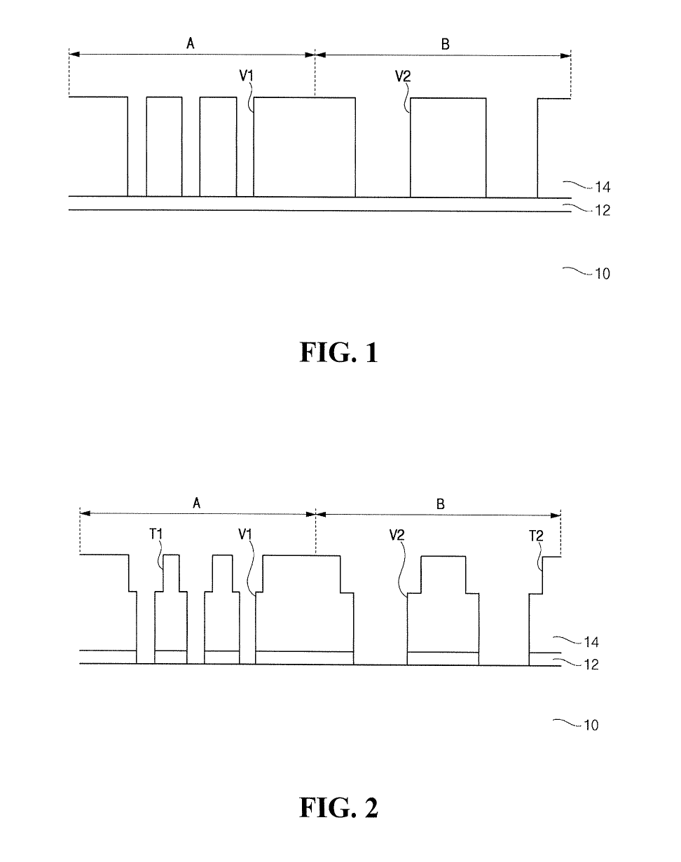

FIGS. 1-6 illustrate a method for fabricating a metal line of a semiconductor device according to an embodiment of the present invention.

Referring to FIG. 1, an etch stop layer 12 and an interlayer insulating layer 14 can be stacked on a substrate 10. The substrate 10 can have a region A where the width of a copper line is narrow, and a region B where the width of a copper line is wide compared to the region A. For example, the width of the copper line in the region B can be at least two times greater than that of the copper line in the region A.

A first via V1 and a second via V2 exposing the etch stop layer 12 are formed through a selective etching process using a photoresist.

Next, referring to FIG. 2, predetermined portions of the interlayer insulating layer 14 are removed using a selective etching process to form first and second trenches T1 and T2 in the upper portions of the first and second vias V1 and V2, respectively.

At this point, the first via V1 and the first trench T1 are formed in the region A where the width of the copper line is narrow. The second via V2 and the second trench T2 are formed in the region B where the width of the copper line is wide.

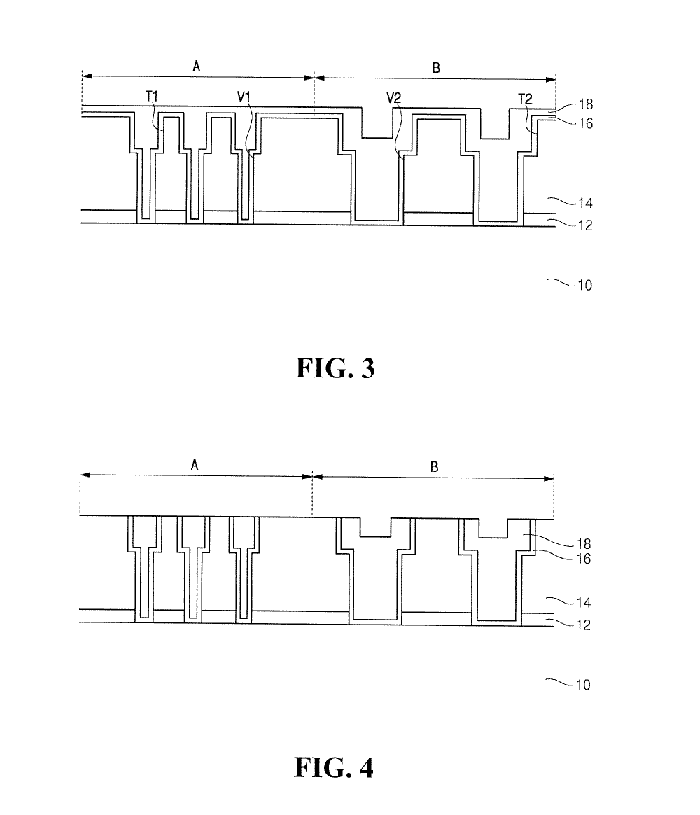

Next, referring to FIG. 3, a seed layer 16 for forming copper can be formed using a stacking process such as sputtering, chemical vapor deposition (CVD), physical vapor deposition (PVD), or atomic layer deposition (ALD).

The first copper layer 18 can be formed through electro-plating. In one embodiment, the electro-plating can be performed for about 10-20 seconds until the vias V1 and V2 are completely filled. At this point, the first copper layer 18 formed along the wall surface of the second trench T2 of the wide region B has a uniform thickness to some extent. That is, the first copper layer 18 formed in the second trench T2 appears to have a trench shape therein, such as shown in FIG. 3.

Meanwhile, the first trench T1 and the first via V1 are completely filled with the first copper layer 18.

Next, referring to FIG. 4, the first copper layer 18 and the seed layer 16 can be polished using CMP until the interlayer insulating layer 14 is exposed.

Therefore, the first copper layer 18 and the seed layer 16 exist only in the vias V1 and V2 and the trenches T1 and T2. Portions of the first copper layer 18 and the seed layer 16 on the interlayer insulating layer 14 connecting the trenches to each other are removed, so that the lines can be open.

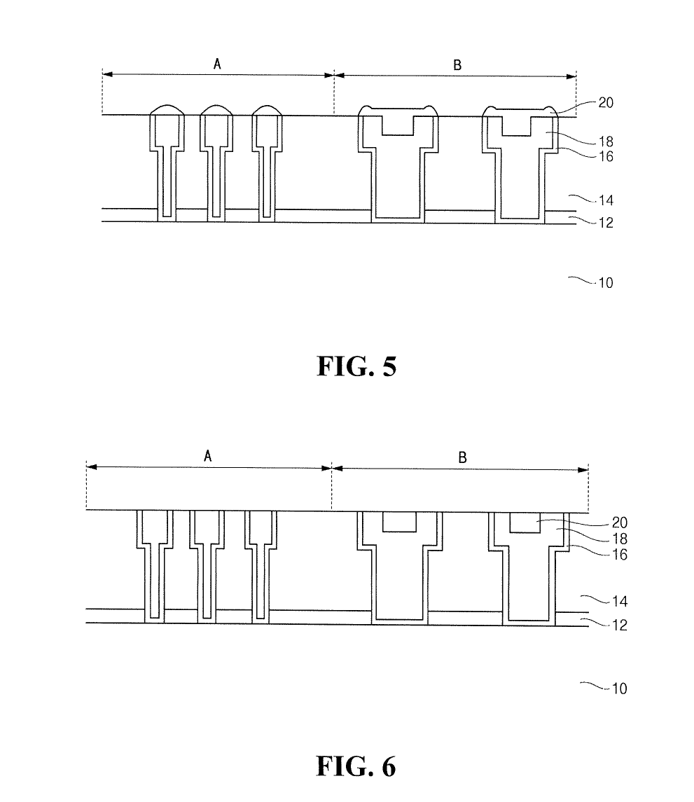

Next, referring to FIG. 5, a second copper layer 20 completely filling the trenches T1 and T2 can be formed through, for example, electroless plating. The second copper layer 20 is formed only in a portion where the first copper layer 18 exists. Although the first and second copper layers 18 and 20 are illustrated as separate elements to explain differences in an aspect of the process, the boundary between the first and second copper layers 18 and 20 may not be discriminated because they are formed of the same material.

Here, since the lines are open (i.e. metal connecting the trenches to each other is removed) and the plating is performed only on the surface of the trenches T1 and T2, electroless plating can be used.

Next, referring to FIG. 6, the second copper layer 20 can be planarized using CMP to form a copper line. Since the copper line is formed after using the electroless plating, a height difference between the copper layer filling the first trench T1 and the copper layer filling the second trench T2 is not large. Therefore, since the copper layers in the second trench and the first trench T2 and T1 are removed at similar speeds, a phenomenon such as dishing is not generated.

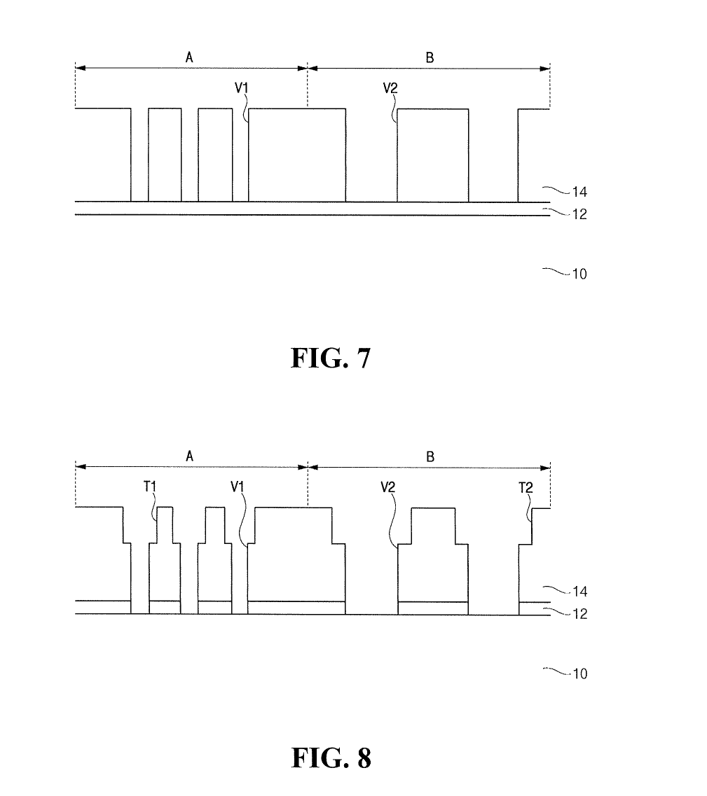

A method for forming a metal line of a semiconductor device according to another embodiment of the present invention will be described with reference to FIGS. 7 to 12.

Referring to FIG. 7, an etch stop layer 12 and an interlayer insulating layer 14 can be stacked on a substrate 10. Subsequently, a first via V1 and a second via V2 exposing the etch stop layer 12 can be formed through a selective etching process using a photoresist.

As in the previous embodiment, the first via V1 is formed in a region A where the width of a copper line is narrow, and the second via V2 is formed in a region B where the width of a copper line is wide.

Next, referring to FIG. 8, predetermined portions of the interlayer insulating layer 14 are removed using a selective etching process to form first and second trenches T1 and T2 in the upper portions of the first and second vias V1 and V2, respectively. According to an embodiment, the width of the second trench T2 is at least two times greater than that of the first trench T1.

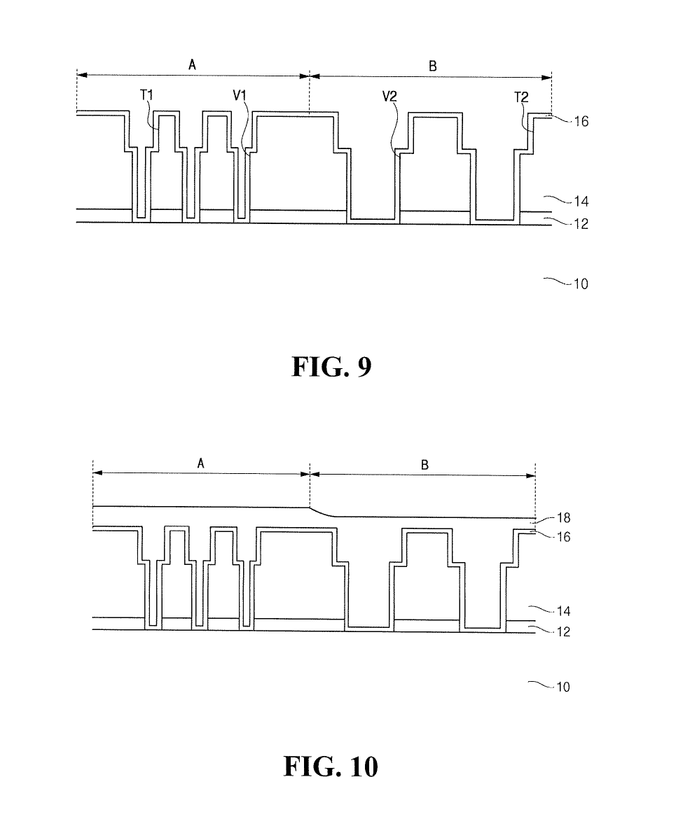

Referring to FIG. 9, a seed layer 16 can be formed in the vias V1 and V2 and trenches T1 and T2 using a stacking process such as sputtering, CVD, PVD, or ALD, to induce forming of a copper layer.

Referring to FIG. 10, a copper layer 18 can be formed using electro-plating. The copper layer 18 is formed to fill the trenches T1 and T2. At this point, the copper layer 18 is formed to different thicknesses depending on the sizes of the vias V1 and V2. Accordingly, a height difference is generated between a portion of the copper layer 18 formed in the first trench T1 and a portion of the copper layer 18 formed in the second trench T2 to cause a dishing phenomenon.

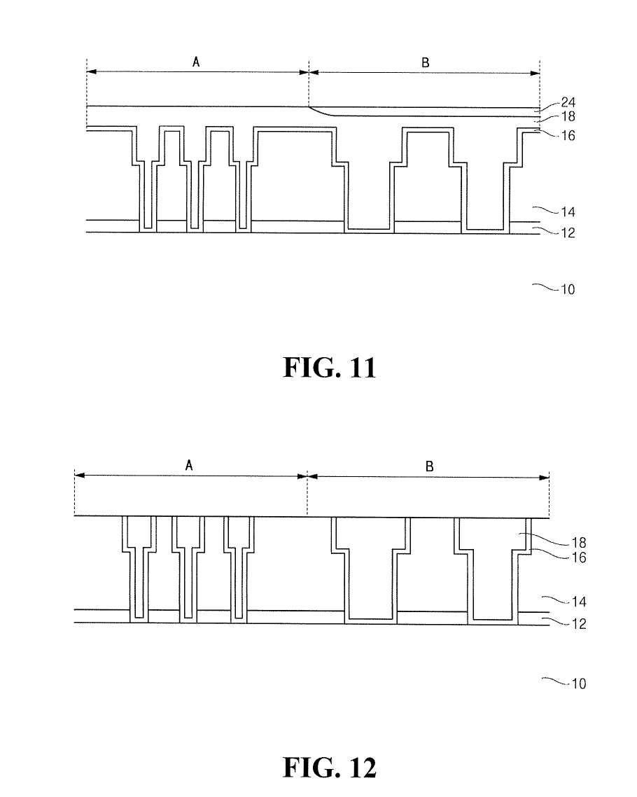

Referring to FIG. 11, a film can be spin-coated on the copper layer 18 to form a sacrificial layer 24, which fills a height difference region where the dishing phenomenon has been generated. As described above, the entire substrate can be made planar by coating the sacrificial layer 24 through the spin coating. According to an embodiment, the sacrificial layer 24 can be formed of SiO₂.

Referring to FIG. 12, the copper layer 18 and the sacrificial layer 24 can be polished using CMP until the interlayer insulating layer 14 is exposed to complete copper line formation. At this point, since the sacrificial layer 24 fills the height difference of the copper layer 18, the planarization process can be performed without influence of the height difference.

As described above, when two plating processes are performed as in the embodiments described with respect to FIGS. 1-6 or spin coating is used as in the embodiments described with respect to claims 7-12, the height difference reduces, so that a planarized substrate can be formed even when a difference in a line width is generated. Therefore, the electrical characteristics of a semiconductor device become uniform and the semiconductor device of high quality can be provided.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a metal line of a semiconductor device, comprising:
forming an interlayer insulating layer on a semiconductor substrate;
forming a first trench and a second trench having a wider width than that of the first trench in the interlayer insulating layer;
forming a seed layer on the semiconductor substrate including the first and second trenches;
forming a first copper layer on the seed layer;
polishing the first copper layer until the interlayer insulating layer is exposed;
forming a second copper layer on the first copper layer; and
planarizing the second copper layer to form a copper line.

2. The method according to claim 1, wherein forming the first copper layer comprises performing electro-plating.

3. The method according to claim 1, wherein polishing the first copper layer comprises using a chemical mechanical polishing process.

4. The method according to claim 1, wherein forming the second copper layer comprises performing electroless plating.

5. The method according to claim 1, wherein polishing the second copper layer comprises using a chemical mechanical polishing process.

6. The method according to claim 1, wherein forming the first copper layer comprises performing electro-plating using copper for 10-20 seconds to form the first copper layer.

7. The method according to claim 1, further comprising forming a first via and a second via having a greater width than the width of the first via in the interlayer insulating layer,
wherein forming the first trench and the second trench comprises:
forming the first trench having a greater width than the width of the first via in an upper portion of the first via, and the second trench having a greater width than the width of the second via in an upper portion of the second via.

8. The method according to claim 7, wherein forming the first copper layer comprises completely filling the first via and the second via with copper.

9. A method for fabricating a metal line of a semiconductor device, comprising:
forming an interlayer insulating layer on a semiconductor substrate;
forming a first trench and a second trench having a wider width than that of the first trench in the interlayer insulating layer;
forming a seed layer on the semiconductor substrate including the first and second trenches;
forming a copper layer on the seed layer;
forming a sacrificial layer on a height difference region of the copper layer generated by a width difference between the first and second trenches to planarize the copper layer; and
polishing the copper layer and the sacrificial layer until the interlayer insulating layer is exposed.

10. The method according to claim 9, wherein forming the copper layer comprises performing electroplating.

11. The method according to claim 9, wherein forming the sacrificial layer comprises performing spin coating.

12. The method according to claim 9, wherein polishing the copper layer and the sacrificial layer comprises performing a chemical mechanical polishing process.

13. The method according to claim 9, wherein the sacrificial layer is formed of SiO₂.

14. The method according to claim 9, further comprising forming a first via and a second via having a greater width than a width of the first via in the interlayer insulating layer,
wherein forming the first trench and the second trench comprises:
forming the first trench having a greater width than the width of the first via in an upper portion of the first via and the second trench having a greater width than the width of the second via in an upper portion of the second via.
